(19) United States
(12) Patent Application Publication
(10) Pub. No.: US 2015/0259824 A1
(43) Pub. Date: Sep. 17, 2015

(54) APPARATUS AND METHODS FOR MANUFACTURING INGOT

(71) Applicants: Hyun Goo Kwon, Uiwang (KR); Yeo Kyun Yoon, Hwaseong (KR); Min Soo Son, Seoul (KR)

(72) Inventors: Hyun Goo Kwon, Uiwang (KR); Yeo Kyun Yoon, Hwaseong (KR); Min Soo Son, Seoul (KR)

(73) Assignee: Technovalue Co., LTD., Seoul (KR)

(21) Appl. No.: 14/257,177

(22) Filed: Apr. 21, 2014

(30) Foreign Application Priority Data
Mar. 13, 2014 (KR) 10-2014-0029833

(51) Int. Cl. C30B 15/00; C30B 30/04

(52) U.S. Cl. CPC C30B 15/005; C30B 15/002; C30B 30/04

(57) ABSTRACT

There is disclosed an ingot manufacture method to grow a first ingot from molten silicon in a crucible, the ingot manufacture method including growing at least a portion of the first ingot in a state where the height of the molten silicon which the crucible is filled with, is kept at a first level for a first period, and changing the height of the molten silicon into a second level different from the first level from the first level for a second period after the first period.

### BACKGROUND OF THE DISCLOSURE

1. Field of the Disclosure

The present invention relates to methods and apparatus for manufacturing ingot.

2. Description of the Related Art

Ingot is important in the manufacture of a semiconductor chip or a solar cell. Silicon is melted and solidified in a crucible to manufacture such ingot.

The ingot is manufactured according to Czochralski method. In the Czochralski method, a rod or seed crystal submerged in molten silicon is slowly lifted and silicon attached to the rod or seed crystal is solidified, only to manufacture ingot.

Recently, studies and developments are under progress on a continuous Czochralski method ingot manufacturing apparatus configured to manufacture a plurality of ingots, using continuously introduced silicon.

### SUMMARY

An object of the disclosure is to provide an ingot manufacture method and an ingot manufacture apparatus, which can disperse positions where the etching is generated on a surface of a crucible by molten silicon.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the embodiments, as embodied and broadly described herein, an ingot manufacture method to grow a first ingot from molten silicon in a crucible includes growing at least a portion of the first ingot in a state where the height of the molten silicon which the crucible is filled with is kept at a first level for a first period; and changing the height of the molten silicon into a second level different from the first level from the first level for a second period after the first period.

The first ingot may continuously grow for the second period.

A second ingot may start to grow from the molten silicon having a height of a third level, which is the same as or larger than the second level, after the first ingot has grown.

A second ingot may start to grow from the molten silicon having a height changed into a second level from the first level less than the second level for a second period, after the first ingot has grown for the first period.

The height of the molten silicon may be changed into the second level from the first level for the second period, while a second ingot grows after the growth of the first ingot for the first period.

The growth rate of the first ingot may be different from the supply rate of the silicon supplied to the crucible for the second period after a portion of the first ingot has grown.

The growth rate of the second ingot may be different from the supply rate of the silicon supplied to the crucible for the second period.

A plurality of the first ingots may grow from the molten silicon having the height of the first level for the first period, and the height of the molten silicon may be changed into the second level from the first level for a second period, after at least a portion of the last one out of the first ingots grows.

The supply rate of the silicon supplied to the crucible may be substantially the same as the growth rate of the first ingot, when the height of the molten silicon is kept at the first level.

The supply rate of the silicon supplied to the crucible may be substantially the same as the growth rate of the second ingot, when the height of the molten silicon is kept at the second level.

The silicon may be supplied to the crucible before the second ingot starts to grow after the first ingot has grown.

A position of an etching portion of the crucible etched by the molten silicon having the height of the first level may be different from a position of an etching portion of the crucible etched by the molten silicon having the height of the second level.

In another aspect, an ingot manufacture method to form molten silicon formed from silicon intermittently or continuously supplied to a crucible in which a first ingot grows, the ingot manufacture method includes changing a height of the molten silicon in a first range of heights for a first period in which at least a portion of the first ingot grows from the molten silicon; and changing the height of the molten silicon in a second range of heights different from the first range for a second period after the first period.

The first ingot may continuously grow when the height of the molten silicon is changed in the second range of heights.

A second ingot may grow from the molten silicon having a height changeable in the second range, after the first ingot has grown from the molten silicon having the height changeable in the first range.

The silicon may be supplied to the crucible before the second ingot starts to grow after the first ingot has grown.

A plurality of the first ingots may grow from the molten silicon for the first period, and the height of the molten silicon may be changed in the second range for the second period after at least a portion of the last one of the first ingots grows.

An etching region of the crucible etched by the molten silicon having the height changeable in the first range may be different from an etching region of the crucible etched by the molten silicon having the height changeable in the second range.

In a further aspect, an ingot manufacture apparatus includes a crucible comprising a melting zone in which molten silicon is formed by melting of silicon and a growth zone in which an ingot grows from the molten silicon; a feeding unit introducing the silicon to the crucible to change the height of the molten silicon while the ingot grows; a heater applying heat the crucible to form the molten silicon; and a shaft moving the crucible in accordance with the height change of the molten silicon, with supporting the crucible.

The shaft may move the crucible to keep a distance between the heater and a surface of the molten silicon constantly in accordance with the height change of the molten silicon.

The shaft may lift the crucible when the height of the molten silicon is decreased, and the shaft may drop the crucible when the height of the molten silicon is increased.

The ingot manufacture apparatus may further include a magnetic field forming unit spaced apart a predetermined distance from the crucible to apply a magnetic field to the molten silicon.

The embodiments have following advantageous effects. The ingot manufacture method and an ingot manufacture apparatus may disperse positions for etching in a crucible, using molten silicon.

The objectives and other advantages of the invention may be realized and attained by the structure particularly pointed out in the written description and claims hereof as well as the appended drawings.

### BRIEF DESCRIPTION OF THE DRAWINGS

The accompanying drawings, which are included to provide a further understanding of the disclosed subject matter and are incorporated in and constitute a part of this specification, illustrate exemplary embodiments of the disclosed subject matter, and together with the description serve to explain the principles of the disclosed subject matter.

FIG. 1 is a diagram illustrating an ingot manufacture apparatus according to one embodiment of the disclosure;

FIG. 2 is a diagram schematically illustrating the ingot manufacture apparatus;

FIGS. 3, 4, 5, 6, 7 and 8 are diagrams illustrating an ingot manufacture method according to one embodiment of the disclosure;

FIGS. 9, 10, 11 and 12 are diagrams illustrating an ingot manufacture method according to another embodiment of the disclosure; and

FIG. 13 is a diagram illustrating an operation of the ingot manufacture apparatus according to one embodiment of the disclosure.

### DETAILED DESCRIPTION OF EXEMPLARY EMBODIMENTS

Hereinafter, exemplary embodiments of the disclosure will be described in detail, referring to the accompanying drawings. For the sake of brief description with reference to the drawings, the same or equivalent components will be provided with the same reference numbers, and description thereof will not be repeated.

The terminology used herein is for the purpose of describing exemplary embodiments only and is not intended to be limiting of the disclosed subject matter. As used herein, the singular forms “a”, “an”, and “the” are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

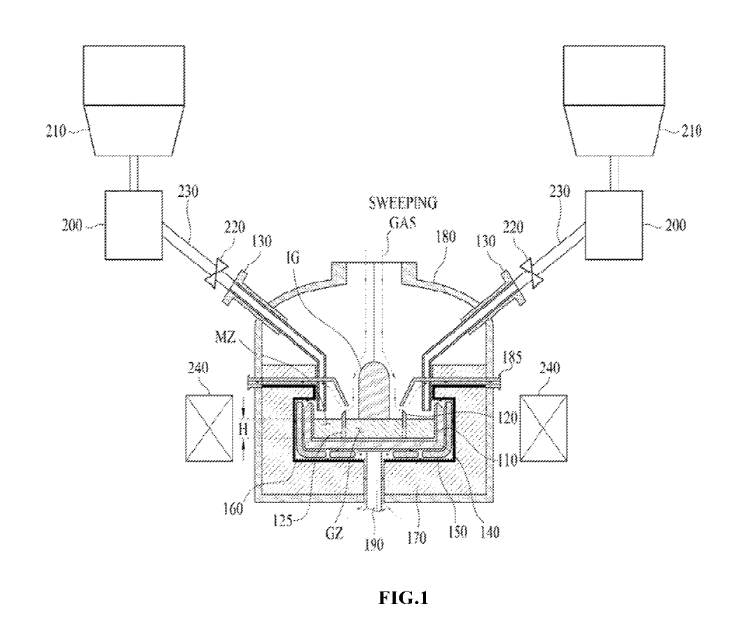

FIG. 1 illustrates an ingot manufacture apparatus according to one embodiment of the disclosure. The ingot manufacture apparatus according to the embodiment of the disclosure may be a continuous Czochralski type (hereinafter CCz type) ingot manufacture apparatus which can intermittently or continuously provide silicon while an ingot (IG) grows.

A crucible 110 may include a melting zone (MZ) in which molten silicon (MS) is formed and a growth zone (GZ) in which an ingot (IG) grows from the molten silicon (MS).

The melting zone (MZ) may be a region between the crucible 110 and an inner wall 120. The growth zone (GZ) may be a region inside the inner wall 120. The inner wall 120 may be provided in the crucible 110 and the molten silicon formed in the melting zone (MZ) may be drawn into the inner wall 120. An inlet 125 may be formed in the inner wall 120 and the molten silicon (MS) may be drawn into the growth zone (GZ) from the melting zone (MZ).

A feeding unit 130 may be configured to introduce silicon to the crucible 110 to change the height of the molten silicon (MS) while the ingot (IG) grows. The feeding unit 130 may be a pipe or tube and the type of the feeding unit 130 may be diverse.

A susceptor 140 may surround the crucible 110. The silicon is melted at a high temperature such that the crucible 110 can get soft. The susceptor 140 may be configured to support the shape of the crucible 110.

A heater 150 may apply heat to the crucible 110 to form the molten silicon (MS). In other words, the heater 150 may heat the crucible 110 to melt the silicon supplied from the feeding unit 130. The heater 150 may be provided adjacent to the susceptor 140. The heater 150 may heat the silicon approximately to 1420r, such that the silicon can be melted in the crucible 110.

A heat shield 160 and an insulator 170 may insulate the heat emitted from the heater 150 and enhance thermal efficiency, only to protect an inner wall of the chamber 180 from a high temperature radiant heat.

A shaft 190 may be connected to the susceptor and support the crucible 110. Unless the susceptor 140 is provided, the shaft 190 can be directly connected to the crucible 110. At this time, the shaft 190 is movable upward and downward to move the crucible 110. The motion of the shaft 190 will be described in detail.

A supply regulating unit 200 may be connected to the feeding unit 130 and the supply regulating unit 200 can regulate a supply rate of the silicon. In this instance, the supply regulating unit 200 may include a vibrator or a screw. The components of the supply regulating unit 200 are not limited thereto. The vibrator may regulate an amplitude or a frequency of vibration such that the supply rate of the silicon can be controlled. A rotation number of the screw may be regulated such that the supply rate of the silicon can be controlled.

A hopper 210 is connected to the supply regulating unit 200 and silicon is stored in the hopper 210. A valve 220 may be provided in a silicon supply pipe 230 to allow or stop the silicon.

An outlet unit 185 may exhaust sweeping gas outside to remove the silicon oxide generated during the growth process of the ingot (IG). Examples of the sweeping gas may include Ar, He and N₂ and not limited thereto.

Hereinafter, an ingot manufacture method according to first to third embodiments of the disclosure will be described, referring to the accompanying drawings.

The ingot manufacture method according to the first to third embodiments may be realized by the ingot manufacture apparatus and not limited thereto. The ingot manufacture method may be realized by apparatuses including different components from the ingot manufacture apparatus shown in FIG. 1.

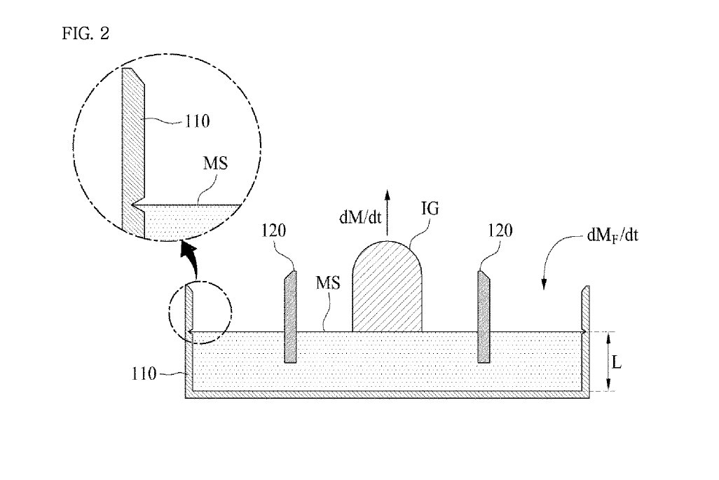

As shown in FIG. 2, the CCz ingot manufacture apparatus may supply silicon to the melting zone (MZ) from the feeding unit 130 while an ingot (IG) grows. Accordingly, the height (L) of the molten silicon (MS), in other words, the maximum distance from a bottom of the crucible 110 to a surface of the molten silicon (MS) can be maintained constantly during the growth of the ingot (IG).

At this time, since the supply rate (dM_{F}/dt) of silicon is the same as the growth rate (dM/dt) of the ingot (IG), the height (L) of the molten silicon (MS) may be maintained constantly.

Meanwhile, a shearing stress may be applied to an inner surface of the crucible 110 along the flow of the molten silicon (MS) and the crucible 110 may be etched by the shearing stress of the molten silicon (MS). Such the strongest shearing stress may be applied to the surface of the molten silicon (MS) and too much etching may be performed between the surface of the molten silicon (MS) and an inner surface of the crucible 110.

With keeping the height of the molten silicon (MS), a plurality of ingots may be manufactured. The more ingots are manufactured, the more severe etching of the crucible 110 is performed. When the etching of the crucible 110 is more severe, the shock or pressure applied to the crucible 110 may damage the crucible 110.

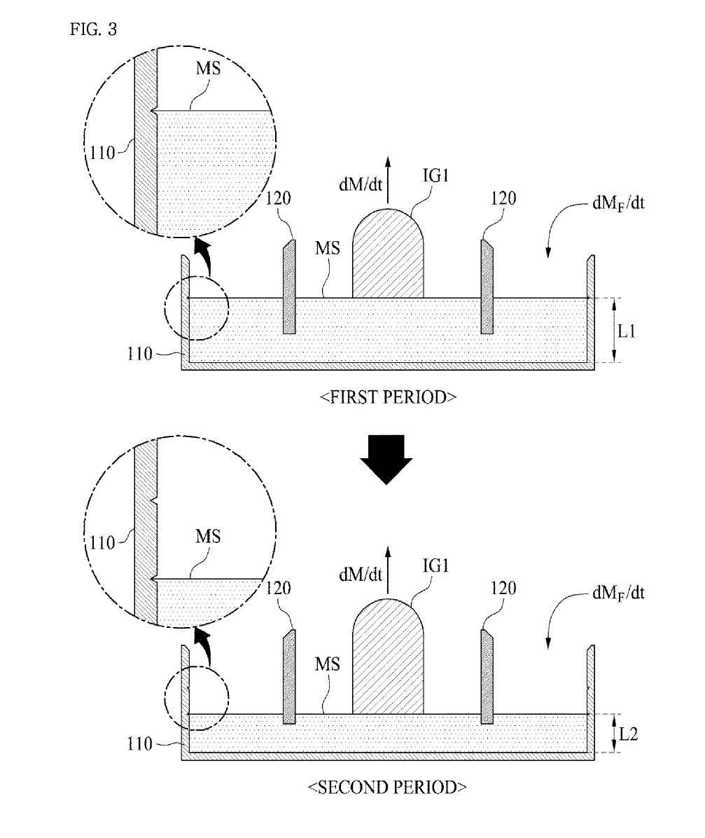

As shown in FIG. 3, in the ingot manufacture method according to the first embodiment, a first ingot (IG1) grows from the molten silicon (MS) in the crucible 110.

At this time, at least of a portion of the first ingot (IG1) grows in a state where the height of the molten silicon (MS) which the crucible 110 is filled with is kept at a first level (L1) for a first period. The silicon may be intermittently or continuously supplied to the melting zone (MZ) for the first period.

The height of the molten silicon (MS) is changed into a second level (L2) different from the first level (L1) from the first level (L1) for a second period after the first period. At this time, the second level (L2) may be smaller or larger than the first level (L1).

The height of the molten silicon (MS) may be changed for the first period and the second period and the etching of the crucible 110 may be performed in a border area between the molten silicon (MS) at the first level (L1) and an inner surface of the crucible 110 and a border area between the molten silicon (MS) at the second level (L2) and the inner surface of the crucible 110.

As shown in FIG. 2, the height of the molten silicon (MS) is kept constantly and the etching is intensively performed in a specific portion of the crucible 110. However, in the ingot manufacture method according to the first embodiment, the height of the molten silicon (MS) is changed and positions in which the etchings are generated may be dispersed.

Accordingly, the ingot manufacture method according to the first embodiment may prevent the etching from being performed at a specific portion of the crucible 110, such that damage to the crucible 110 may be prevented.

The change in the heights of the molten silicon (MS) may be generated during the growth process of the first ingot (IG1) or after the first ingot (IG1) has grown.

As shown in FIG. 3, the height of the molten silicon (MS) is changed while the first ingot (IG1) grows and the growth of the first ingot (IG1) may be performed continuously for the second period.

After a portion of the first ingot (IG1) grows, the growth rate of the first ingot (IG1) may be different from the supply rate of the silicon supplied to the crucible 110 for the second period. Accordingly, the height of the molten silicon (MS) may be changed into the second level (L2) from the first level (L1).

For instance, as shown in FIG. 3, when the growth rate (dM/dt) of the first ingot (IG1) is greater than the supply rate (dM_{F}/dt) of the silicon, the height of the molten silicon (MS) may be lowered into the second level (L2) from the first level (L1).

As not shown in FIG. 3, the growth rate (dM/dt) of the first ingot (IG1) is less than the supply rate (dM_{F}/dt) of the silicon, the height of the molten silicon (MS) may be heightened to the second level (L2) from the first level (L1).

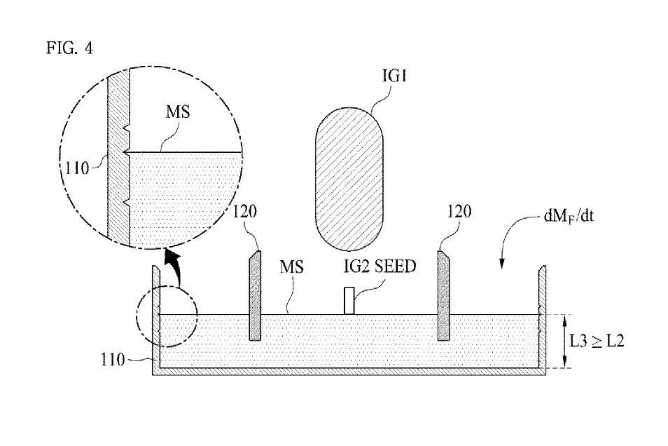

As shown in FIG. 4, when the growth of the first ingot (IG1) is completed after the growth of the first ingot (IG1) for the second period, the first ingot (IG1) is taken out from the chamber 180 and a seed (S) for manufacturing a second ingot (IG2) is introduced into the chamber 180.

Before the second ingot (IG2) starts to grow after the growth of the first ingot (IG1), there may be no ingot growing from the molten silicon (MS). Unless the silicon supplied to the crucible 110, the height of the molten silicon (MS) is kept at the second level (L2).

In contrast, when silicon is supplied to the crucible 110 before the second ingot (IG2) starts to grow after the growth of the first ingot (IG1), the height of the molten silicon (MS) may be higher than the second level (L2).

Once the growth of the first ingot (IG1) is completed after the growth for the second period, the second ingot (IG2) may start to grow from the molten silicon (MS) having a third level (L3) which is the same as or higher than the second level (L2).

Hereinabove, it is described that the first ingot (IG1) continuously grows for the second period after partially growing for the first period. Hereinafter, it will be described that the growth of the first ingot (IG1) is completed for the first period.

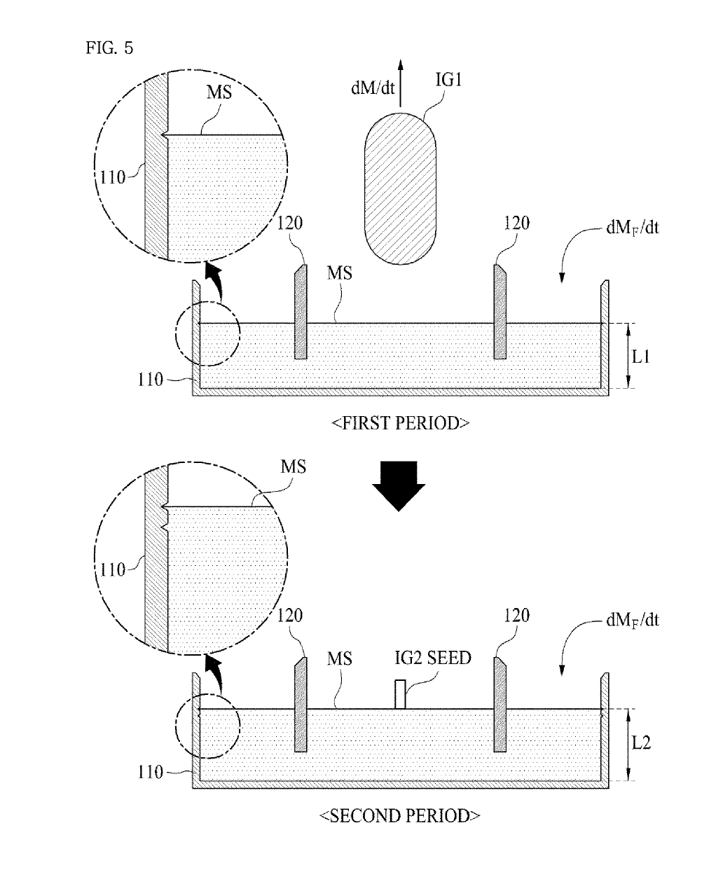

As shown in FIG. 5, the first ingot (IG1) may grow from the molten silicon (MS) having the first level (L1) for the first period. After the growth of the first ingot (IG1) is completed, a seed (S) for the second ingot (IG2) is introduced into the chamber 180 and the second ingot (IG2) may start to grow.

At this time, the second ingot (IG2) may start to grow from the molten silicon having the height changed into the second level (L2) from the first level (L1) less than the second level (L2) for the second period after the growth of the first ingot (IG1) is completed for the first period. In other words, silicon is supplied to the crucible 110 before the second ingot (IG2) starts to grow after the first ingot (IG1) has grown, such that the height of the molten silicon (MS) may be increased to the second level (L2) from the first level (L1).

As mentioned above, no ingot grows while the seed (S) is introduced after the growth of the first ingot (IG1) and the height of the molten silicon (MS) may be increased to the second level (L2), as silicon is supplied. The growth of the second ingot (IG2) may start from the molten silicon (MS) having the second level (L2). Accordingly, positions of the etching portions of the crucible 110 may be dispersed and the possibility of damage to the crucible 110 can be reduced.

In case the height of the molten silicon (MS) is kept at the second level (L2) during the growth of the second ingot (IG2), the supply rate (dM_{F}/dt) of the silicon supplied to the crucible 110 may be substantially the same as the growth rate (dM/dt) of the second ingot (IG2).

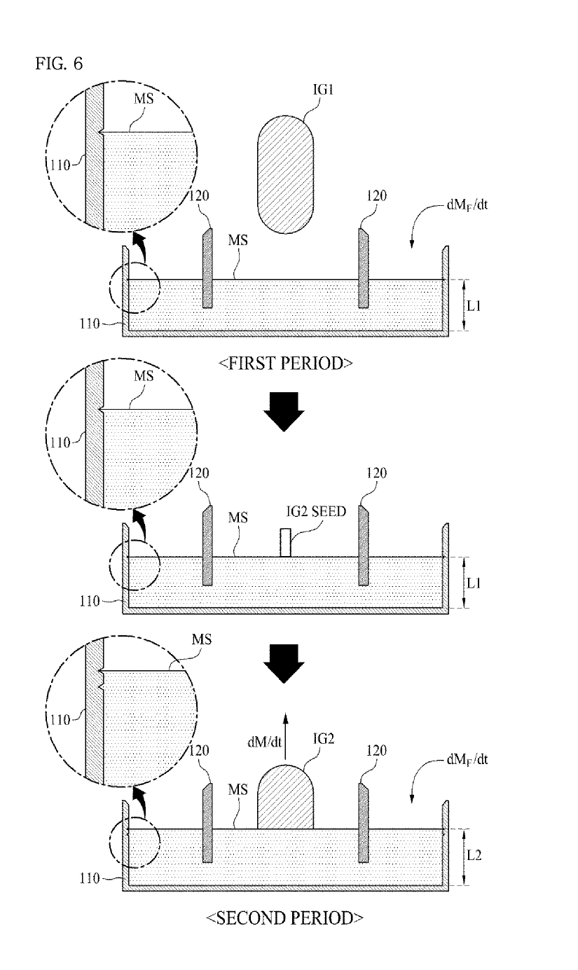

Unlike the disclosure above, as shown in FIG. 6, the height of the molten silicon (MS) may be changed into the second level (L2) from the first level (L1) for the second period, while the second ingot (IG2) grows after the growth of the first ingot (IG1) has grown for the first period.

For instance, the first ingot (IG1) may have grown from the molten silicon (MS) having the height of the first level (L1) for the first period. After that, the first ingot (IG1) may be discharged from the chamber 180 and the seed (S) may be introduced into the chamber 180, with keeping the height of the molten silicon (MS) at the first level (L1). Hence, the height of the molten silicon (MS) is changed into the second level (L2) from the first level (L1) for the second period while the second ingot (IG2) grows. The positions of etching portions of the crucible 110 may be dispersed through such the process.

At this time, the growth rate (dM/dt) of the second ingot (IG2) for the second period may be different from the supply rate (dM_{F}/dt) of the silicon to the crucible 110, such that the height of the molten silicon (MS) can be changed into the second level (L2) from the first level (L1).

Meanwhile, a plurality of the first ingots (IG1) may grow from the molten silicon (MS) having the height of the first level (L1) for the first period. At this time, after at least a portion of the last one out of the first ingots (IG1) grows, the height of the molten silicon (MS) may be changed into the second level (L2) from the first level (L1) for the second period.

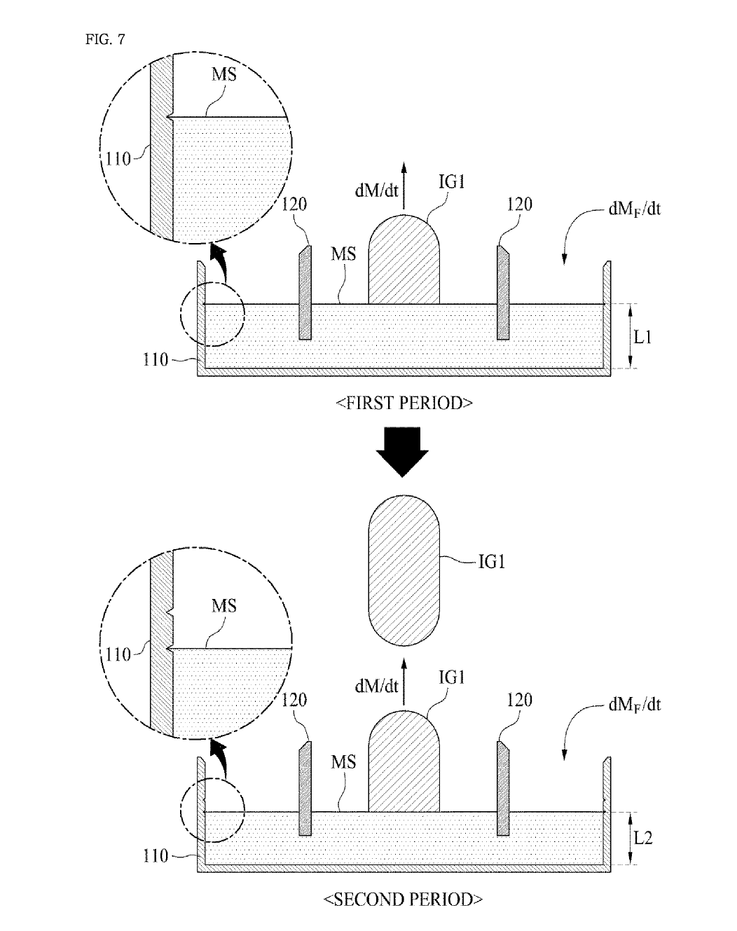

For instance, when two first ingots (IG1) are manufactured for the first period, the last one of the two first ingots (IG1) partially grows and the height of the molten silicon (MS) may be then changed into the second level (L2) from the first level (L1), as shown in FIG. 7.

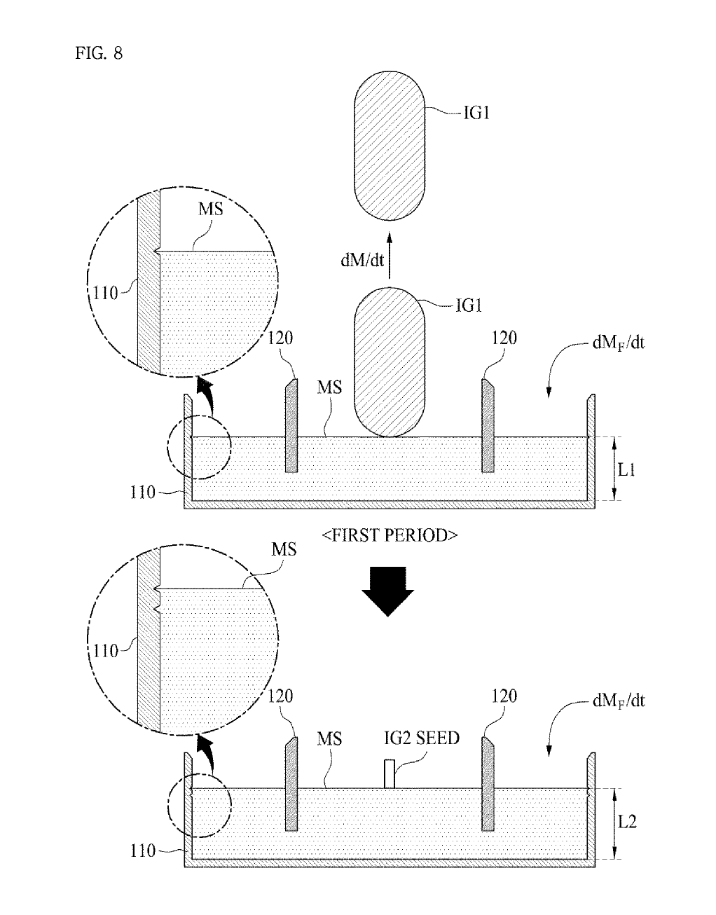

There may be another example different from the example shown in FIG. 7. As shown in FIG. 8, while the two first ingots (IG1) have grown, the height of the molten silicon (MS) is kept at the first level (L1) and the height of the molten silicon (MS) may be changed into the second level (L2) from the first level (L1) for the second period, with the seed (S) for the second ingot (IG2) introduced into the chamber.

Although not shown in the drawings, the seed (S) for growing the second ingot (IG2) may be introduced in a state where the height of the molten silicon (MS) is kept at the first level (L1) after the plurality of the first ingots (IG1) have grown from the molten silicon (MS) having the height of the first level (L1). After that, the height of the molten silicon (MS) may be changed into the second level (L2) from the first level (L1) for the second period during the growth of the second ingot (IG2).

As mentioned above, positions of the etching portions of the crucible 110 may be dispersed and the damage to the crucible 110 can be prevented.

Meanwhile, when the height of the molten silicon (MS) is kept at the first level (L1), the supply rate of the silicon supplied to the crucible 110 may be substantially the same as the growth rate of the first ingot (IG1).

While the first ingot (IG1) grows, silicon is supplied through the feeding unit 130 intermittently or continuously. As the supply rate of the silicon is substantially the same as the growth rate of the first ingot (IG1), the height of the molten silicon (MS) may be kept constantly.

As mentioned above, the ingot manufacture method according to the first embodiment may differentiate a position of the portion of the crucible 110 etched by the molten silicon (MS) having the height of the first level (L1) and a position of the portion of the crucible 110 etched by the molten silicon (MS) having the height of the second level (L2) from each other, only to disperse positions of the etching portions of the crucible 110 performed by the molten silicon (MS).

Hereinafter, an ingot manufacture method according to a second embodiment of the disclosure will be described, referring to the accompanying drawings.

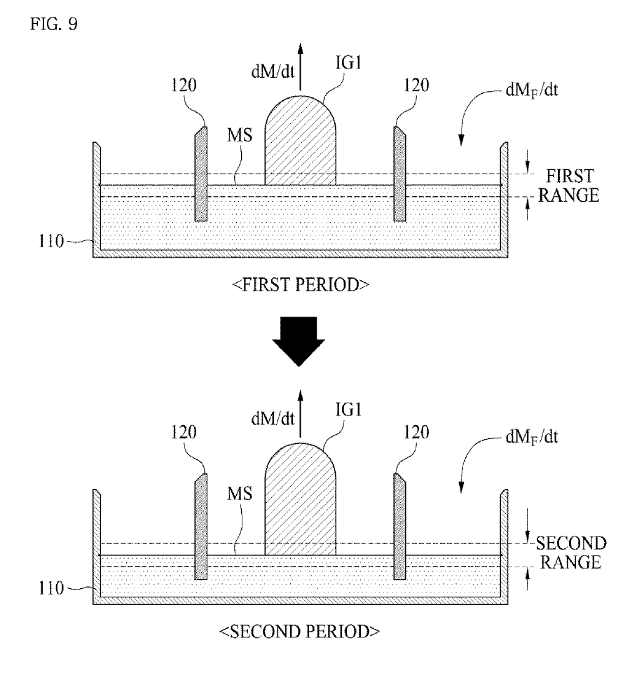

As shown in FIG. 9, in the ingot manufacture method according to the second embodiment, silicon is melted in a crucible 110 to form molten silicon (MS) and a first ingot (IG1) grows from the molten silicon (MS).

In this instance, the height of the molten silicon (MS) is changed in a first range of heights for a first period in which at least a portion of the first ingot (IG1) grows from the molten silicon (MS). The height of the molten silicon (MS) may be changed in a second range of heights, which is different from the first range, for a second period after the first period.

For instance, the first range may be a first reference level −a<the first reference level<the first reference level+a. The second range may be a second reference level−b<the second reference level<the second reference level+b.

At this time, a and b are positive numbers, and a and b are different values smaller than the first reference level and the second reference level, respectively. The first reference level and the second reference level may be the same as or different from each other. When the first reference level is the same as the second reference level, a and b may be different from each other.

Accordingly, positions of the etching portions of the crucible 110 performed by the molten silicon may be dispersed.

When the height of the molten silicon is changed in the second range of heights, the first ingot (IG1) may grow continuously. For instance, a portion of the first ingot (IG1) may grow from the molten silicon (MS) having the height which is changeable in the first range. The other portion of the first ingot (IG1) may grow from the molten silicon (MS) having the height which is changeable in the second range.

Accordingly, Positions of the portions etched by the molten silicon (MS) may be dispersed in an inner surface of the crucible 110 while the first ingot (IG1) grows.

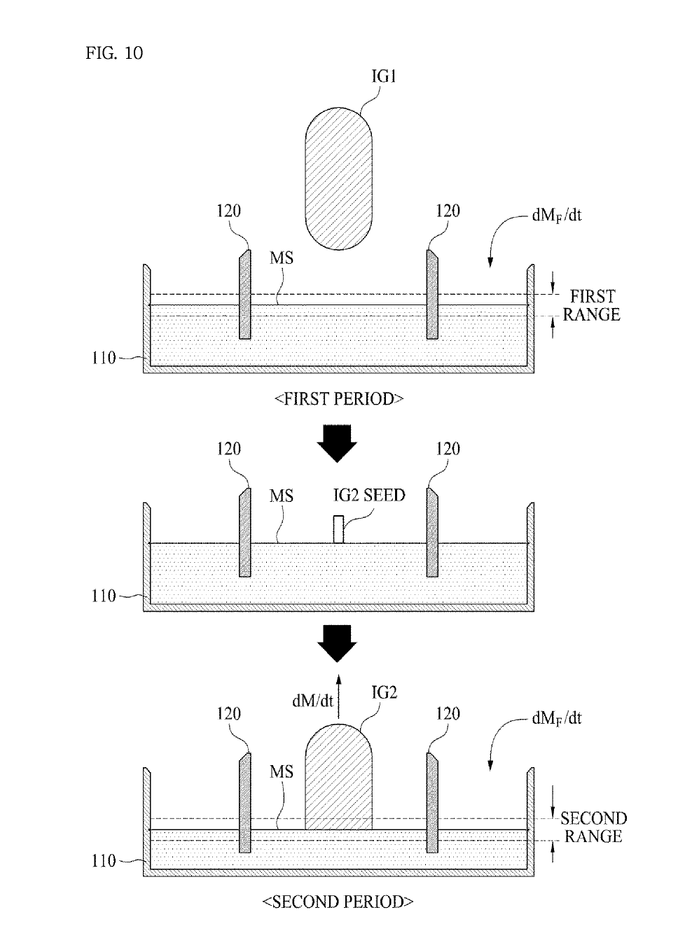

As shown in FIG. 10, the first ingot (IG1) has grown from the molten silicon (MS) having a height changeable in the first range of heights and a seed (S) for growing a second ingot (IG2) is then introduced in a chamber 180. After that, the second ingot (IG2) may grow from the molten silicon (MS) having a height changeable in a second range. Accordingly, the range of the heights of the molten silicon (MS) at which the first ingot (IG1) grows may be different from the range of the heights of the molten silicon (MS) at which the second ingot (IG2) grows, such that positions of the etching portions of the molten silicon (MS) can be dispersed in an inner surface of the crucible 110.

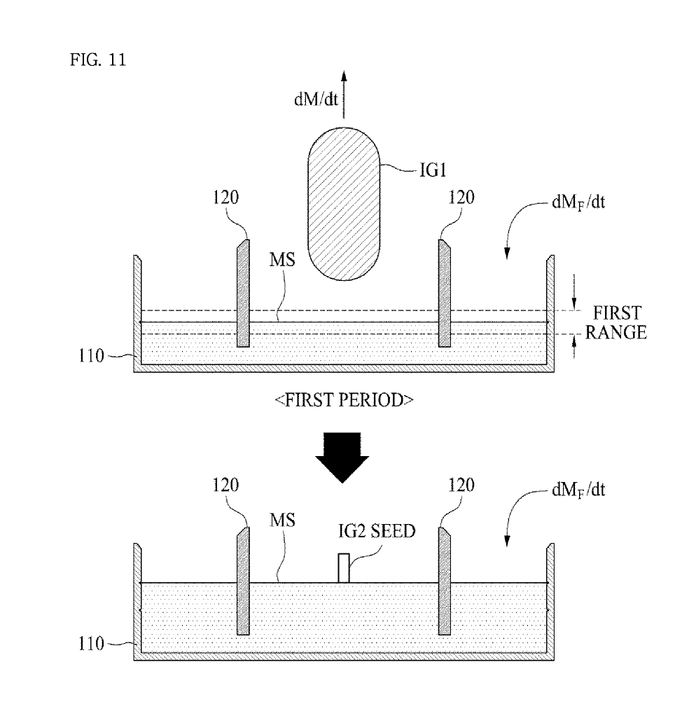

Before the second ingot (IG2) starts to grow after the first ingot (IG1) has grown, silicon may be supplied to the crucible 110 as shown in FIG. 11. The height of the molten silicon (MS) may be increased such that positions of the etching portions of the crucible 110 may be dispersed.

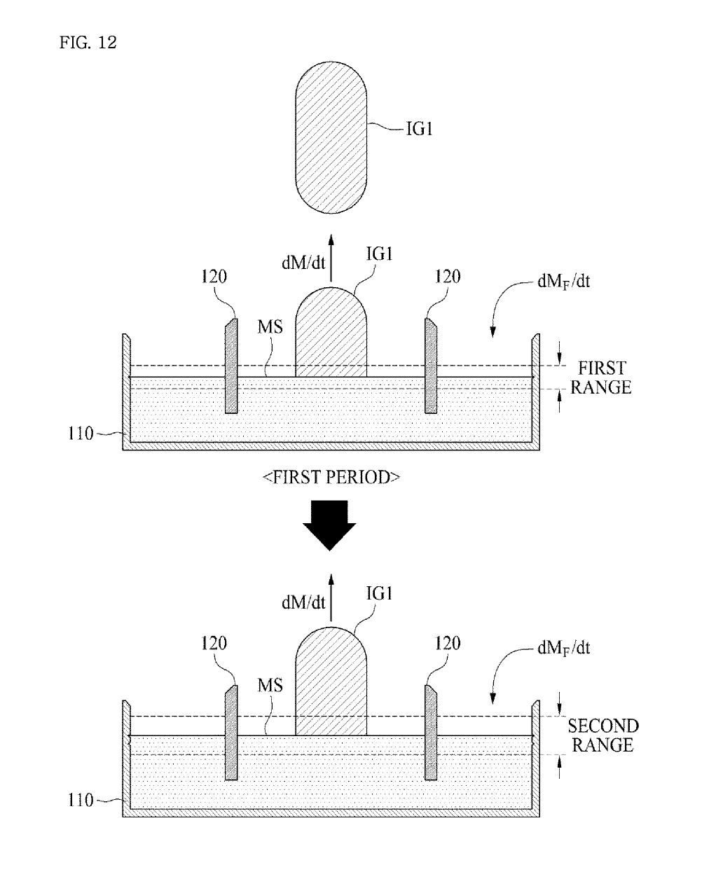

As shown in FIG. 12, a plurality of the first ingots (e.g., two first ingots) may grow from the molten silicon (MS) for a first period. The plurality of the first ingots (IG1) may grow from the molten silicon (MS) having a first range of changeable heights.

After at least a portion of the last one out of the plurality of the first ingots (IG1) grows, the height of the molten silicon (MS) may be changed in a second range for a second period.

It is shown in FIG. 12 that the height of the molten silicon (MS) is changed in the second range after at least a portion of the last one out of the two ingots has grown. Alternatively, the height of the molten silicon (MS) can be changed in the second range after the last one of the two first ingots (IG1) has grown.

Accordingly, the ingot manufacture method according to the second embodiment may differentiate the range of the heights of the molten silicon (MS) while the ingot grows, only to disperse positions of the etching portions of the crucible 110.

In other words, an etching region of the crucible 110 etched by the molten silicon (MS) having the height changeable in the first range may be different from an etching region of the crucible etched by the molten silicon (MS) having the height changeable in the second range.

Next, an operation of the ingot manufacture apparatus according to the embodiment will be described.

As mentioned above, referring to FIG. 1, the shaft 190 may move the crucible 110 in accordance with a height change of the molten silicon (MS).

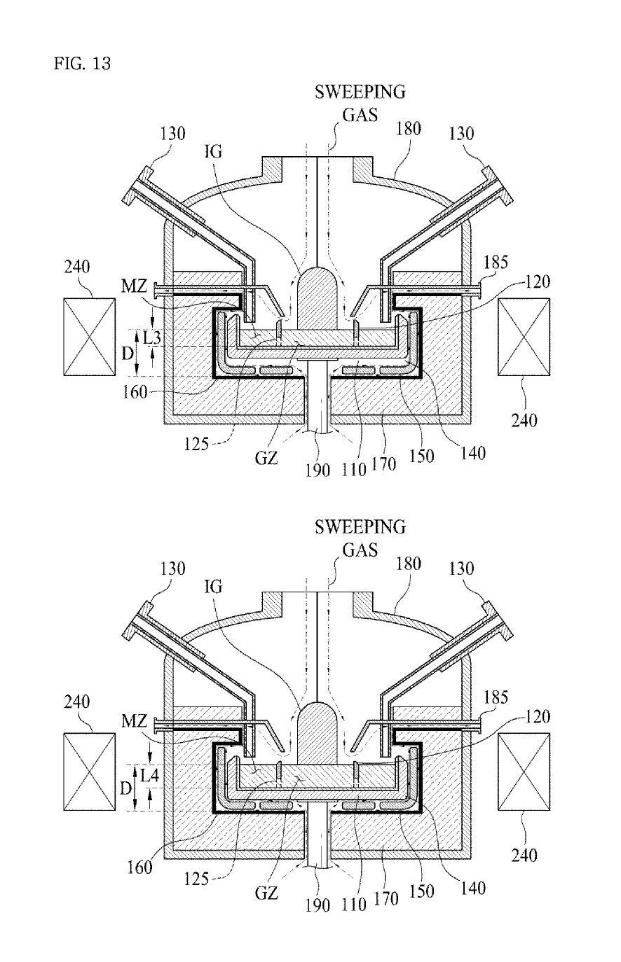

As shown in FIG. 13, the shaft 190 may move the crucible 110 to keep a distance (D) between the heater 150 and a surface of the molten silicon (MS) constantly according to the height change of the molten silicon (MS). At this time, the distance (D) may be the shortest distance from the heater 150 mounted under the molten silicon (MS) to the surface of the molten silicon (MS).

The distance (D) between the heater 150 and the surface of the molten silicon (MS) is kept constantly. Accordingly, even when the height of the molten silicon (MS) is changed, the amount of the changed heat applied to the molten silicon (MS) may be reduced and the growth of the ingot may be performed in a stable environment in the chamber 180.

To keep the distance (D) between the heater 150 and the surface of the molten silicon (MS), the shaft 190 may lift the crucible 110 when the height of the molten silicon (MS) is decreased, and drop the crucible 10 when the height of the molten silicon (MS) is increased.

Meanwhile, the ingot manufacture apparatus according to the embodiment of the disclosure may further include a magnetic field forming unit 240 spaced apart a predetermined distance from the crucible 110 to apply a magnetic field to the molten silicon (MS). The magnetic field forming unit 240 may include a coil and a current supply unit (not shown) to provide the coil with alternating currents.

As mentioned above, when the silicon is melted, conductivity of the molten silicon is increased. When the magnetic field forming unit 240 applies to the magnetic field to the molten silicon (MS), convection of the molten silicon (MS) may be reduced.

The etching of the crucible 110 may be performed by the flow of the molten silicon (MS). Accordingly, when the convection of the molten silicon (MS) is reduced, the etching of the crucible 110 could be reduced.

When the magnetic field forming unit 240 applies the magnetic field to the molten silicon (MS), the etching of the crucible 110 may be reduced.

The operation of the shaft 190 may be performed by a hydraulic pressure or a motor and the driving force of the shaft may not be limited thereto. The motion of the shaft 190 may be performed by various driving units.

Various variations and modifications of the refrigerator described above are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An ingot manufacture method to grow a first ingot from molten silicon in a crucible, the ingot manufacture method comprising:
growing at least a portion of the first ingot in a state where the height of the molten silicon which the crucible is filled with is kept at a first level for a first period; and
changing the height of the molten silicon into a second level different from the first level from the first level for a second period after the first period.

2. The ingot manufacture method of claim 1, wherein the first ingot continuously grows for the second period.

3. The ingot manufacture method of claim 2, wherein a second ingot starts to grow from the molten silicon having a height of a third level, which is the same as or higher than the second level, after the first ingot has grown.

4. The ingot manufacture method of claim 1, wherein a second ingot starts to grow from the molten silicon having a height changed into a second level from the first level less than the second level for a second period, after the first ingot has grown for the first period.

5. The ingot manufacture method of claim 1, wherein the height of the molten silicon is changed into the second level from the first level for the second period, while a second ingot grows after the growth of the first ingot for the first period.

6. The ingot manufacture method of claim 2, wherein the growth rate of the first ingot is different from the supply rate of the silicon supplied to the crucible for the second period after a portion of the first ingot grows.

7. The ingot manufacture method of claim 5, wherein the growth rate of the second ingot is different from the supply rate of the silicon supplied to the crucible for the second period.

8. The ingot manufacture method of claim 1, wherein a plurality of the first ingots grow from the molten silicon having the height of the first level for the first period, and
the height of the molten silicon is changed into the second level from the first level for a second period, after at least a portion of the last one out of the first ingots grows.

9. The ingot manufacture method of claim 1, wherein the supply rate of the silicon supplied to the crucible is substantially the same as the growth rate of the first ingot, when the height of the molten silicon is kept at the first level.

10. The ingot manufacture method of claim 4, wherein the supply rate of the silicon supplied to the crucible is substantially the same as the growth rate of the second ingot, when the height of the molten silicon is kept at the second level.

11. The ingot manufacture method of claim 4, wherein the silicon is supplied to the crucible before the second ingot starts to grow after the first ingot has grown.

12. The ingot manufacture method of claim 1, wherein a position of an etching portion of the crucible etched by the molten silicon having the height of the first level is different from a position of an etching portion of the crucible etched by the molten silicon having the height of the second level.

13. An ingot manufacture method to form molten silicon formed from silicon intermittently or continuously supplied to a crucible in which a first ingot grows, the ingot manufacture method comprising:
changing a height of the molten silicon in a first range of heights for a first period in which at least a portion of the first ingot grows from the molten silicon; and
changing the height of the molten silicon in a second range of heights different from the first range for a second period after the first period.

14. The ingot manufacture method of claim 13, wherein the first ingot continuously grows when the height of the molten silicon is changed in the second range of heights.

15. The ingot manufacture method of claim 13, wherein a second ingot grows from the molten silicon having a height changeable in the second range, after the first ingot has grown from the molten silicon having the height changeable in the first range.

16. The ingot manufacture method of claim 15, wherein the silicon is supplied to the crucible before the second ingot starts to grow after the first ingot has grown.

17. The ingot manufacture method of claim 13, wherein a plurality of the first ingots grow from the molten silicon for the first period, and
the height of the molten silicon is changed in the second range for the second period after at least a portion of the last one of the first ingots grows.

18. The ingot manufacture method of claim 13, wherein an etching region of the crucible etched by the molten silicon having the height changeable in the first range is different from an etching region of the crucible etched by the molten silicon having the height changeable in the second range.

19. An ingot manufacture apparatus comprising:
a crucible comprising a melting zone in which molten silicon is formed by melting of silicon and a growth zone in which an ingot grows from the molten silicon;
a feeding unit introducing the silicon to the crucible to change the height of the molten silicon while the ingot grows;
a heater applying heat the crucible to form the molten silicon; and
a shaft moving the crucible in accordance with the height change of the molten silicon, with supporting the crucible.

20. The ingot manufacture apparatus of claim 19, wherein the shaft moves the crucible to keep a distance between the heater and a surface of the molten silicon constantly in accordance with the height change of the molten silicon.

21. The ingot manufacture apparatus of claim 19, wherein the shaft lifts the crucible when the height of the molten silicon is decreased, and
the shaft drops the crucible when the height of the molten silicon is increased.

22. The ingot manufacture apparatus of claim 19, further comprising:
a magnetic field forming unit spaced apart a predetermined distance from the crucible to apply a magnetic field to the molten silicon.
